(19) United States
(12) Patent Application Publication
(10) Pub. No.: US 2011/0279401 A1
(43) Pub. Date: Nov. 17, 2011

(54) ONE-LAYER CAPACITIVE TOUCH SCREEN AND METHOD OF MANUFACTURING THE SAME

(75) Inventors: Yun Ki HONG, Gyungi-do (KR); Hee Bum LEE, Gyunggi-do (KR); Kyoung Soo CHAE, Gyunggi-do (KR); Yong Soo OH, Gyunggi-do (KR); Jong Young LEE, Gyunggi-do (KR); Dong Sik YOO, Seoul (KR)

(73) Assignee: SAMSUNG ELECTRO-MECHANICS CO., LTD., Gyunggi-do (KR)

(21) Appl. No.: 12/852,298

(22) Filed: Aug. 6, 2010

(30) Foreign Application Priority Data
May 14, 2010 (KR) 10-2010-0045630

(51) Int. Cl. G06F 3/045; H05K 3/10

(52) U.S. Cl. 345/174; 29/846

(57) ABSTRACT

Disclosed herein are a one-layer capacitive touch screen and a method of manufacturing the same. The one-layer capacitive touch screen includes: a base substrate; a first electrode pattern that is formed on an upper surface of the base substrate and includes a plurality of first sensing units and first connection units connecting the adjacent first sensing units; a second electrode pattern that is formed on the upper surface of the base substrate and includes a plurality of second sensing units and second connection units connecting the adjacent second sensing units, the second connection units being formed to intersect with each other on the upper side of the first connection unit, having an air gap therebetween; and an electrode wiring that is connected to the first electrode pattern and the second electrode.

### CROSS REFERENCE TO RELATED APPLICATION

This application claims the benefit of Korean Patent Application No. 10-2010-0045630, filed on May 14, 2010, entitled “One-Layer Type Touch Screen and Method Of Manufacturing The Same,” which is hereby incorporated by reference in its entirety into this application.

### BACKGROUND OF THE INVENTION

1. Technical Field

The present invention relates to a one-layer capacitive touch screen and a method of manufacturing the same.

2. Description of the Related Art

A touch screen is an input device that inputs corresponding instructions by pressing icons displayed on a terminal with an input unit such as fingers or a stylus pen. The touch screen has expanded in various fields.

With the recent development of a mobile communication technology, user terminals such as cellular phones, PMPs, PDAs, and navigational devices can serve as a display device that simply displays character information as well serve as a complex device for providing various and complex multi-media such as audio, moving picture, radio internet, web browser, etc. As a result, the touch screen that can implement a larger display screen in a terminal having a limited size has been in the limelight as an input device.

The touch screen is generally classified into a resistive type and a capacitive type. A research on a capacitive touch screen has been actively conducted due to a recent demand for multi-touch devices.

The capacitive touch screen is largely classified into two types. First, the self capacitance type measures the change in capacitance of a plurality of electrode patterns by forming the electrode patterns on a substrate and connecting electrode wirings to the electrode patterns in order to recognize a touch. Even though the self capacitance type is simple in a driving scheme, it should form a plurality of independent electrode patterns and connect electrode wirings to each electrode pattern. Consequently, there are problems in that the constitution and the manufacturing process of the self capacitance type touch screen are complicated.

The second type is the mutual capacitance type which forms a lattice structure by using two types of electrode patterns, one being formed in an X-axis direction and the other being formed in a Y-axis direction, and then sequentially measures capacitance formed at both electrode patterns to calculate coordinates of contact points. The mutual capacitance type is classified into a two-layer structure and a one-layer structure. There is a problem in that the mutual capacitance type touch screen having the two-layer structure increases the thickness of the touch screen since two types of electrode patterns are positioned on different planes.

On the other hand, in the one-layer mutual capacitance type touch screen, two types of electrode patterns are positioned on the same plane. The mutual capacitance type touch screen having a one-layer structure has a bridge structure at an intersecting point so that two types of electrode patterns are not electrically connected to each other. The bridge structure according to the prior art means a structure where one of two types of electrode patterns is positioned at a lower side and the other is positioned at an upper side, having an insulating pattern between the electrode patterns.

The bridge structure configures capacitors having the insulating patterns there between to form the parasitic capacitance between two types of electrode patterns. The parasitic capacitance serves as noise at the time of measuring the contact point of the input unit. When the input unit contacts the touch screen, the coordinates of the contact points are obtained by measuring the change in capacitance between two types of electrode patterns and the input unit. However, when the parasitic capacitance is large, the capacitance may be shown higher or lower than an actual value due to the capacitance occurring between the input unit and the electrode pattern. Therefore, there is a problem in reducing the accuracy of the touch screen. Further, there is a problem in that the touch screen needs separate components to remove noise.

### SUMMARY OF THE INVENTION

The present invention has been made in an effort to provide a one-layer capacitive touch screen and a method of manufacturing the same that is capable of reducing parasitic capacitance occurring in a bridge structure by forming electrode patterns having an air gap there between rather than forming the electrode patterns having an insulating pattern there between.

A one-layer capacitive touch screen according to a preferred embodiment of the present invention includes: a base substrate: a first electrode pattern that is formed on an upper surface of the base substrate and includes a plurality of first sensing units and first connection units connecting the adjacent first sensing units; a second electrode pattern that is formed on the upper surface of the base substrate and includes a plurality of second sensing units and second connection units connecting the adjacent second sensing units, the second connection units being formed to intersect with each other on the upper side of the first connection unit, having an air gap therebetween; and an electrode wiring that is connected to the first electrode pattern and the second electrode pattern.

The one-layer capacitive touch screen further includes a protective layer that is formed on the base substrate and covers the first electrode pattern, the second electrode pattern, and the electrode wiring.

The first electrode pattern and the second electrode pattern are made of conductive polymer.

The first sensing unit and the second sensing unit are formed in a polygonal shape.

There is provided a method of manufacturing a one-layer capacitive touch screen, including: forming a first electrode pattern, which includes a plurality of first sensing units and first connection units connecting the adjacent first sensing units, on the upper surface of a base substrate; forming an insulating pattern on the first connection unit; forming a second electrode pattern, which includes a plurality of second sensing units and second connection units connecting the adjacent second sensing units and disposed on the insulating pattern, on the upper surface of the base substrate; and removing the insulating pattern.

The method of manufacturing a one-layer capacitive touch screen further includes forming electrode wiring that is connected to the first electrode pattern and the second electrode pattern.

The method of manufacturing a one-layer capacitive touch screen further includes after the removing the insulating pattern, forming a protective layer to cover the first electrode pattern, the second electrode pattern, and the electrode wiring.

The forming the insulating pattern is performed by bonding an insulating film having an adhesive layer formed on one surface thereof on the first connection unit.

The forming the insulating pattern is performed by spotting a semisolid insulating material on the first connection unit.

The forming the insulating pattern forms the insulating pattern to cover the side surface and upper surface of the first connection unit.

At the time, the forming the first electrode pattern and the second electrode pattern, the first electrode pattern and the second electrode pattern are formed by an inkjet printing scheme.

There is provided a method of manufacturing a one-layer capacitive touch screen, including: forming a plurality of first connection units in an array on an upper surface of a base substrate; forming an insulating pattern on the first connection unit; forming a second connection unit that is formed on the insulating pattern and has both distal ends to be formed on the base substrate; forming a first electrode pattern on the upper surface of the base substrate by forming a first sensing unit connecting to the first connection unit and forming a second electrode pattern by forming a second sensing unit connecting to the second connection unit; and removing the insulating pattern.

The method of manufacturing a one-layer capacitive touch screen further includes forming electrode wiring connected to the first electrode pattern and the second electrode pattern.

The method of manufacturing a one-layer capacitive touch screen further includes forming a protective layer to cover the first electrode pattern, the second electrode pattern, and the electrode wiring.

The forming the insulating pattern is performed by bonding an insulating film having an adhesive layer on one surface thereof to the first connection unit.

The forming the insulation pattern is performed by spotting a semisolid insulating material on the first connection unit.

At the time, the forming the first electrode pattern and the forming the second electrode pattern, the first electrode pattern and the second electrode pattern are formed by an inkjet printing scheme.

### BRIEF DESCRIPTION OF THE DRAWINGS

FIG. 1 is a perspective view of a one-layer capacitive touch screen according to the present invention;

FIG. 2 is a perspective view of a one-layer capacitive touch screen according to another embodiment of the present invention;

FIGS. 3 to 14 are plan views and cross-sectional views showing a method of manufacturing a touch screen according to a first embodiment of the present invention; and

FIGS. 15 to 28 are plan views and cross-sectional views showing a method of manufacturing a touch screen according to a second embodiment of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, in describing the present invention, a detailed description of related known functions or configurations will be omitted so as not to obscure the subject of the present invention.

Hereinafter, preferred embodiments of the present invention will be described in detail with reference to the accompanying drawings.

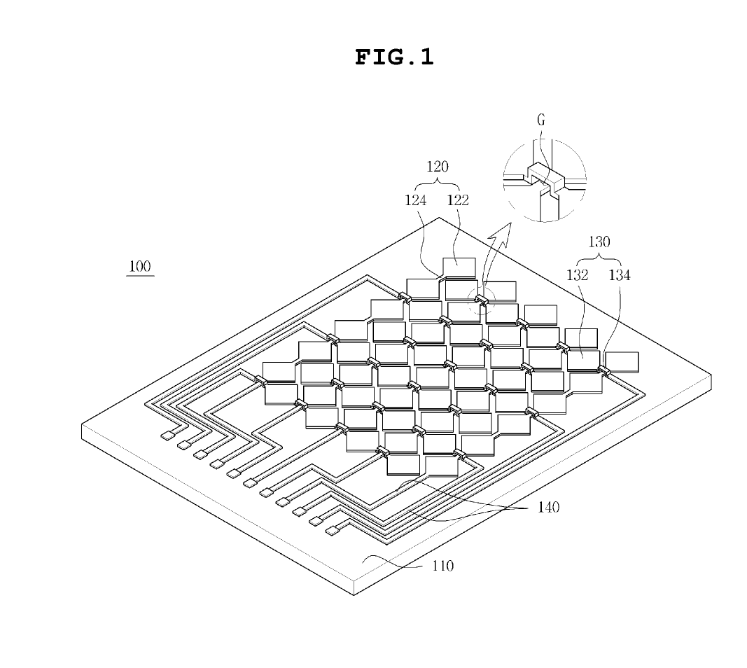

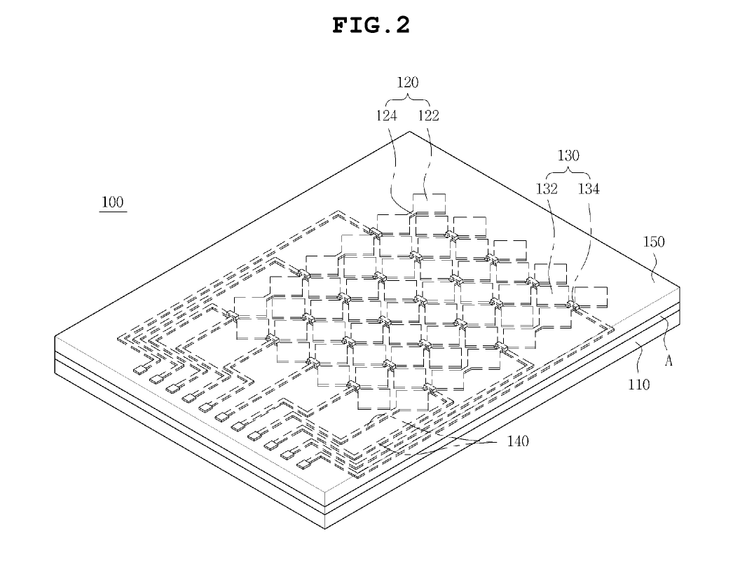

FIG. 1 is a perspective view of a one-layer capacitive touch screen according to the present invention and FIG. 2 is a perspective view of a one-layer capacitive touch screen according to another embodiment of the present invention. Hereinafter, a method of manufacturing a one-layer capacitive touch screen according to the present invention will be described with reference to FIGS. 1 and 2.

A one-layer capacitive touch screen 100 includes a base substrate, a first electrode pattern and a second electrode pattern that intersect with each other in a bridge structure that measures the change in capacitance according to a contact of an input unit, and electrode wirings connected to the electrode patterns.

As the base substrate 110, a glass substrate, a film substrate, a fiber substrate, etc., which are a transparent member, may be used.

First electrode patterns 120 and second electrode patterns 130, which intersect with each other, are formed in an active region of the base substrate 110. The active region is a region through which images generated in the display pass and touched by the input unit.

First, the first electrode pattern 120 and the second electrode pattern 130 are made of a transparent conductive material such ITO, carbon nanotube, etc. In particular, it is preferable that they are made of conductive polymer. The conductive polymer is made of organic based compounds, which are flexible and are inexpensive for manufacturing costs. The conductive polymer may include polythiophene, polypyrrole, polyaniline, polyacetylene, polyphenylene, or the like. In particular, among the polythiophene, PEDOT/PSS compound is most preferable.

The plurality of first electrode pattern 120 are formed on the upper surface of the base substrate in a first direction (Y direction) in parallel and have a shape where first sensing units 122 and first connection units 124 are repeated. At this time, the first sensing unit 122 measures the change in capacitance when a user's hand touches the touch screen and the first connection unit 124 connects the plurality of first sensing units 122.

Meanwhile, although the first sensing unit 122 has a diamond shape in FIG. 1, this is provided by way of example only. Therefore, the first sensing unit 122 may be formed in other polygonal shapes.

The second electrode pattern 130 is formed on the upper surface of the base substrate 110 like the above-mentioned first electrode pattern 120 and is made of the same material as the first electrode pattern 120. Further, the plurality of second electrode patterns 130 are formed in parallel in a second direction (X direction) and have a shape where second sensing units 132 and second connection units 134 are repeated. The plurality of second electrode patterns 130 are formed to have a bridge structure and thus, electrically separated from each other without connecting to the first electrode patterns 120.

Describing the bridge structure where the first electrode pattern 120 and the second electrode pattern 130 are formed, the second connection units 134 are formed on the first connection unit 124 formed on the base substrate 110 to intersect with each other, having an air gap G there between. In the prior art, the bridge structure is formed to have an insulating pattern having high dielectric constant between the first connection unit and the second connection unit, such that the significant parasitic capacitance may occur. The present invention forms the bridge structure having the air gap (G), having a very low dielectric constant between the first connection unit 124 and the second connection unit 134, thereby making it possible to minimize the occurrence of the parasitic capacitance.

The plurality of electrode wirings 140 are formed in the inactive region of the base substrate 110. A portion of the electrode wirings are connected to the first electrode patterns 120 and the remaining electrode wirings are connected to the second electrode patterns 130. At this time, the inactive region means a region that prevents images to pass through an edge region of the base substrate 110.

The electrode wirings 140 are made of a conductive material having low resistance like silver (Ag) and the distal ends thereof are disposed to be collected at the edge of the base substrate 110. The edge regions at which the distal ends of the electrode wirings 140 are collected are called a connection unit. The connection unit is connected to an FPCB (not shown) and transfers the change in capacitance of the electrode pattern to the capacitance sensor (not shown).

The touch screen 100 according to another embodiment of the present invention further includes a protective layer 150 that covers the first electrode pattern 120 and the second pattern 130 formed on the base substrate 110. The protective layer 150 may be made of the same material as the above-mentioned base substrate 110, may form a touch surface touched by a user's fingers, and may be bonded by optical adhesive A.

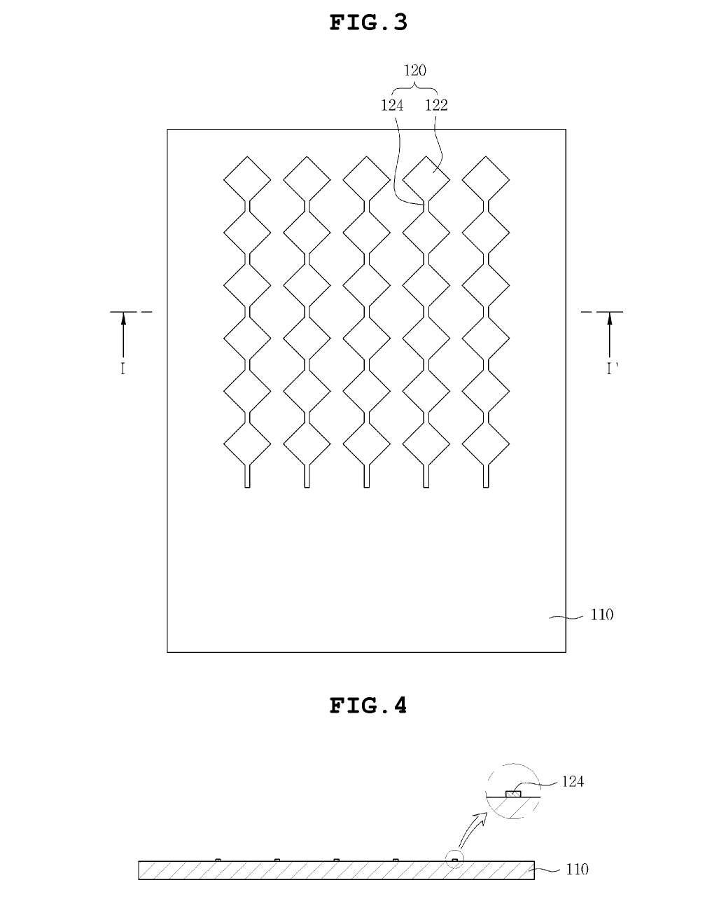

FIGS. 3 to 14 are plan views and cross-sectional views showing a method of manufacturing a touch screen according to a first embodiment of the present invention. Hereinafter, a method of manufacturing a capacitive touch screen according to the embodiment of the present invention will be described below.

First, as shown in FIGS. 3 and 4, the plurality of first electrode patterns 120 are formed in the active region of the base substrate 110. At this time, although the first electrode pattern 120 is formed in the Y direction, this is by way of example only. The capacitive touch screen is manufactured by forming the first electrode pattern in a vertical direction to the second electrode pattern 130.

At this time, it is preferable that the first electrode pattern 120 is formed by an inkjet printing scheme. The conductive ink is filled in an inkjet apparatus and is then printed on the base substrate 110 to form the first sensing unit 122 and the first connection unit 124.

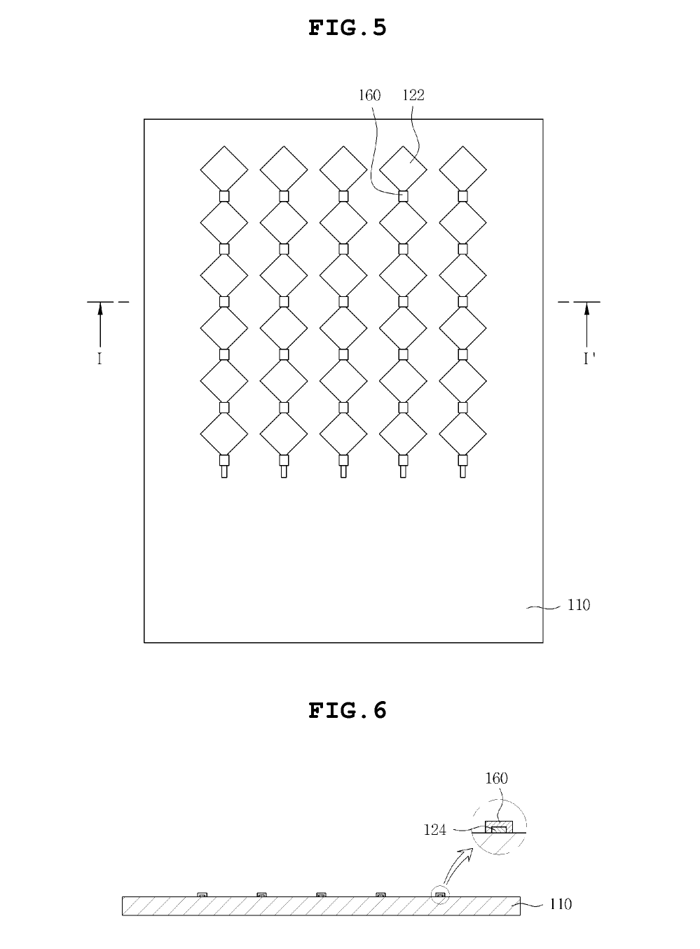

Next, referring to FIGS. 5 and 6, an insulating layer 160 is formed on the first connection unit 124 of the first electrode pattern 120. The insulating pattern 160 is made of plastic resin and when the first electrode pattern and the second electrode pattern are formed on the same plane, prevents a short from occurring in the connection unit.

As shown in FIGS. 5 and 6, the insulating pattern 160 may be formed by bonding an insulating film on the first connection unit 124, wherein the insulating film has an adhesive layer formed on one surface thereof.

Further, the insulating pattern may be formed by spotting a semisolid insulating material formed on the first connection unit 124. This scheme has an advantage in that the insulating pattern can be accurately positioned by only using a small amount of insulating material.

It is preferable that the insulating pattern 160 is formed to cover the side surface and the upper surface of the first connection unit 124. The insulating pattern 160 having the above-mentioned shape prevents the possibility that the second connection unit 134 will be connected to the first connection unit 124 when the second electrode pattern 130 is formed without being exposed to the outside of the first connection unit 124.

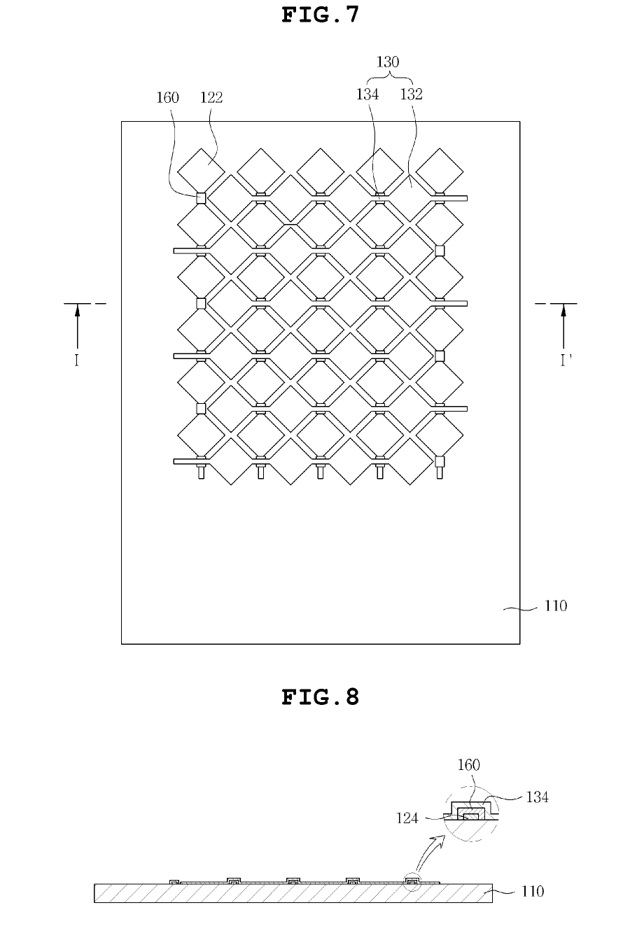

Next, as shown in FIGS. 7 and 8, the plurality of second electrode patterns 130 are formed on the base substrate 110. At this time, the second sensing unit 132 is formed in the residual space in which the first sensing unit 122 of the first electrode pattern 120 is formed and the second connection unit 134 connecting the second sensing unit 132 is formed on the insulating pattern 160, such that the second electrode pattern 130 is not connected to the first electrode pattern 120.

It is preferable that in the second electrode pattern 130, the second sensing unit 132 and the second connection unit 134 are formed as one body by the inkjet printing scheme. The second sensing unit 132 and the second connection unit 134 are continuously formed simultaneously, thereby simplifying the manufacturing process and improving productivity.

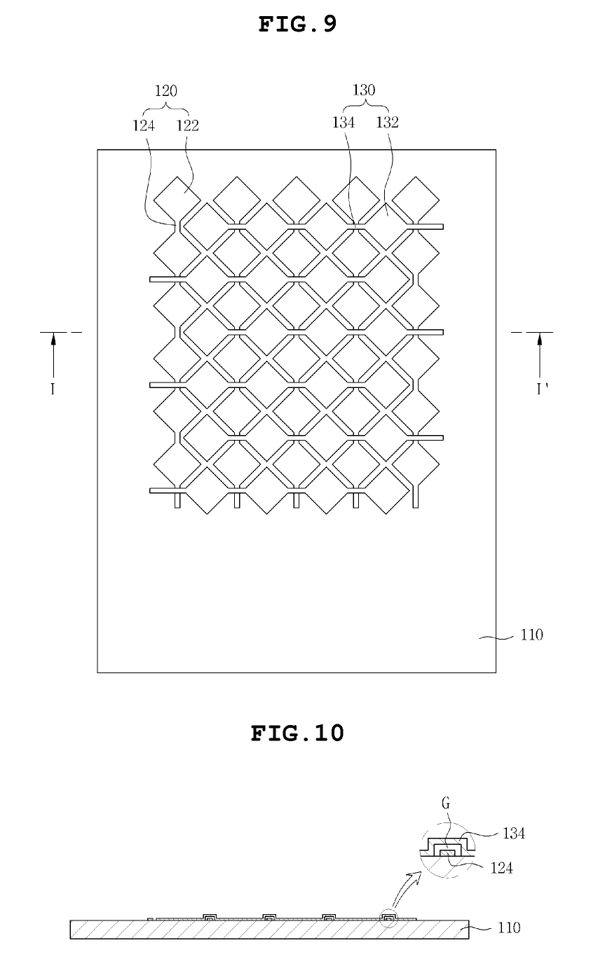

As shown in FIGS. 9 and 10, the insulating pattern 160 formed between the first connection unit 124 and the second connection unit 134 is removed. The insulating pattern 160 may be removed by an etching scheme or a peeling scheme. The etching scheme removes the insulating pattern 160 by melting the insulating pattern 160 using an etching solution and the peeling scheme removes the insulating pattern 160 by weakening the adhesion of the insulating pattern 160 using a peeling solution. At this time, the etching solution and the peeling solution are known materials and the composition thereof is not specifically limited.

When the insulating pattern 160 is removed, the air gap G is generated between the first connection unit 124 and the second connection unit 134 and the shape of the air gap G is determined by the shape of the insulating pattern 160. Since the second connection unit 134 is also formed on the insulating pattern 160, it is determined by the shape of the insulating pattern 160.

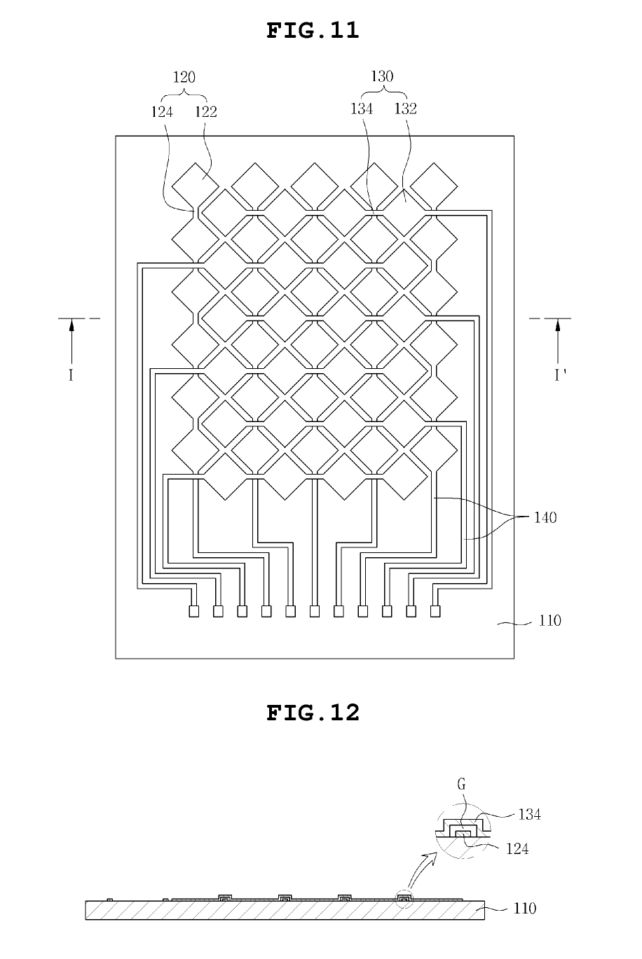

As shown in FIGS. 11 and 12, the method of manufacturing a touch screen according to the present invention further includes forming the plurality of electrode wirings 140 connected to the first electrode pattern 120 and the second electrode pattern 130. The electrode wiring 140 is formed in the inactive region of the base substrate 110 and may be formed by an inkjet scheme, a photolithography scheme, a gravure printing scheme, and so on.

However, it is not limited to the method when the electrode wiring 140 is formed after removing the insulating pattern 160. The electrode wiring 140 may be previously formed in the inactive region prior to forming the electrode patterns 120 and 130, the electrode wiring 140 connected to the first electrode pattern 120 may be formed after the electrode patterns 120 and 130 are formed to connect to the electrode wiring 140 or the electrode wiring 140 connected to the first electrode pattern 120 may be formed after forming the first electrode pattern, and the electrode wiring 140 connected to the second electrode pattern 130 may further formed after the second electrode pattern 130 is formed.

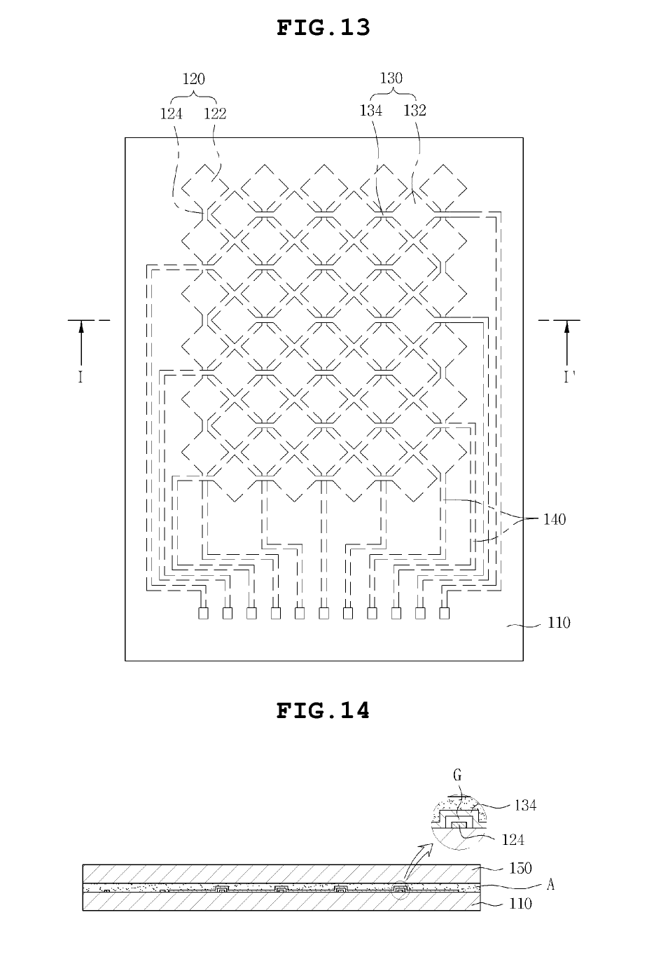

Further, as shown in FIGS. 13 and 14, the method of manufacturing a touch screen according to the present invention may further include forming the protective layer 150 to cover the first electrode pattern 120, the second electrode pattern 130, and the electrode wiring 140 formed on the base substrate 110.

The protective layer 150 may be formed by bonding the glass substrate or the film substrate using the optical adhesive A. In particular, the protective layer 150 may be formed by a laminating scheme when being formed as the film substrate.

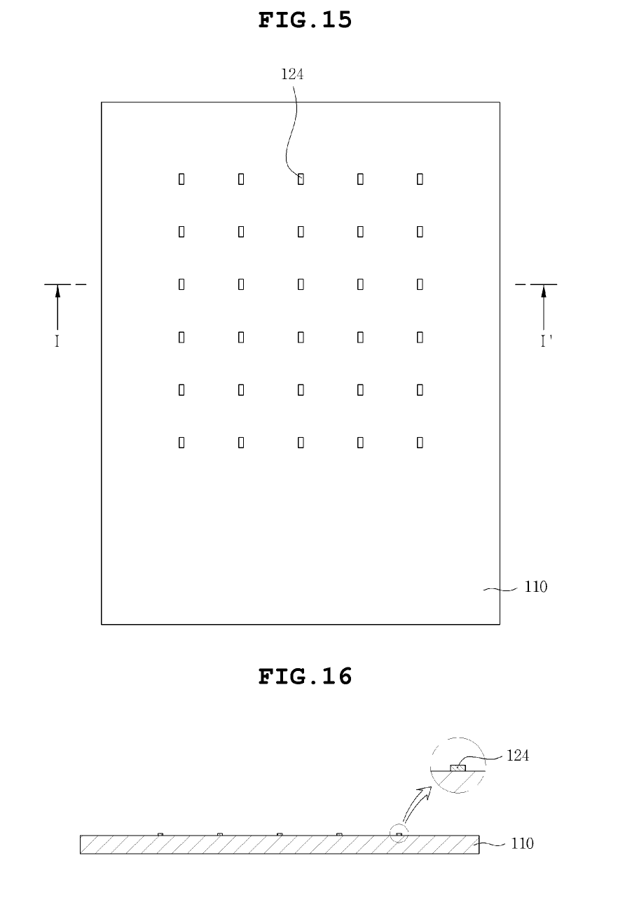

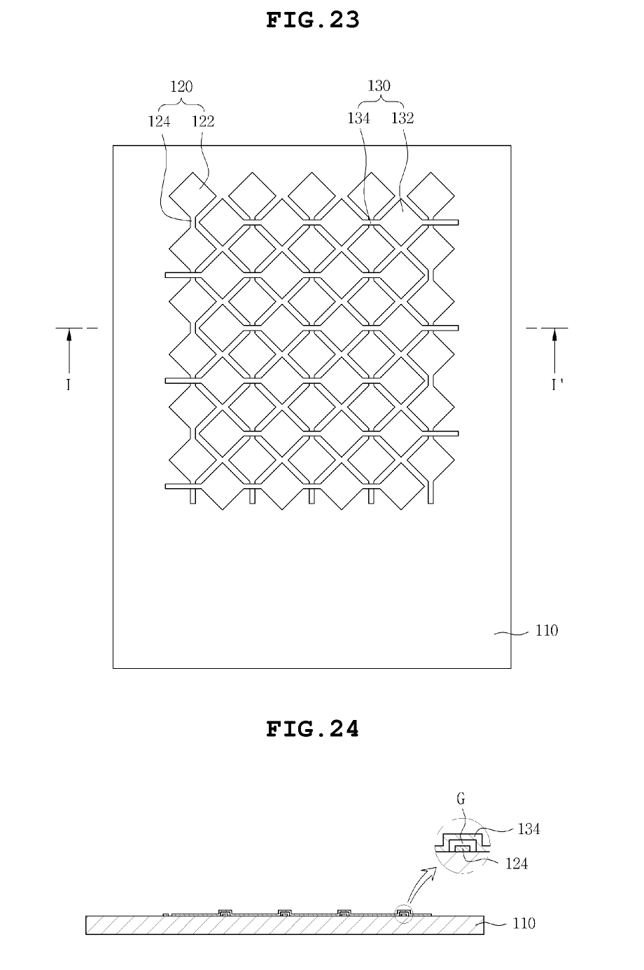

FIGS. 15 to 28 are plan views and cross-sectional views showing a method of manufacturing a touch screen according to a second embodiment of the present invention. Hereinafter, a method of manufacturing a one-layer capacitive touch screen according to the embodiment of the present invention will be described below. A detailed description of the same manufacturing process as that described with reference to FIGS. 3 to 14 will be omitted.

First, as shown in FIGS. 15 and 16, the plurality of first connection parts 124 are formed in the active region of the base substrate 110. It may be performed by the inkjet printing scheme, etc. In FIG. 15, it is formed in an array form of 5×6, but is by way of example only. Therefore, it may be modified and practiced.

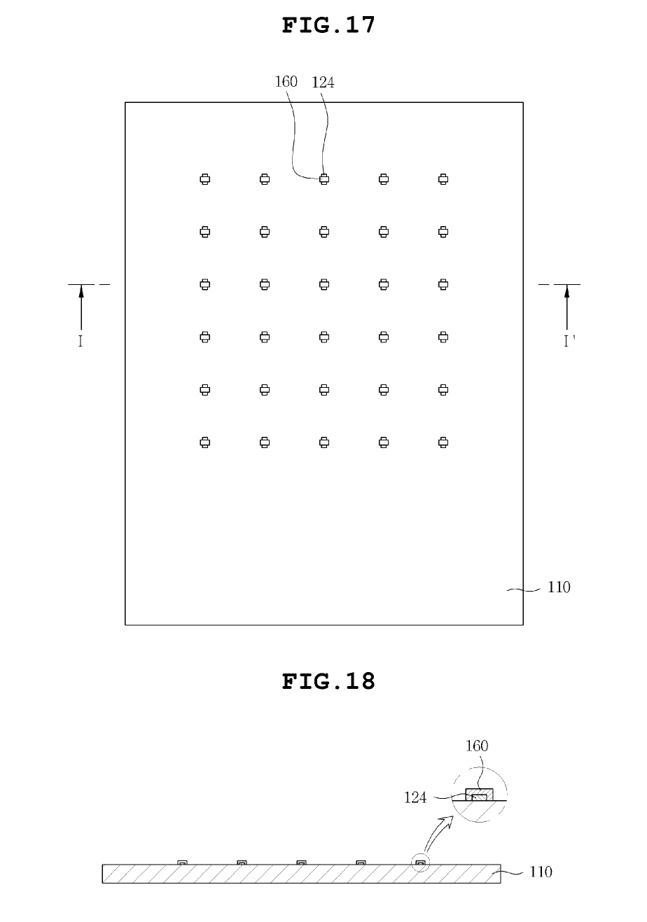

Next, as shown in FIGS. 17 and 18, the insulating pattern 160 is formed on the plurality of first connection units 124. The insulating pattern may be formed by a scheme described with reference to FIGS. 5 and 6. It is formed to intersect with the first connection unit 124 and is formed in the X direction to expose both ends of the first connection unit 124. In FIGS. 17 and 18, the insulating pattern 160 is formed on all the first connection units 124 formed in the base substrate 110. However, it is sufficient when the insulating pattern 160 is formed only on the first connection unit 124 which will substantially form the bridge structure.

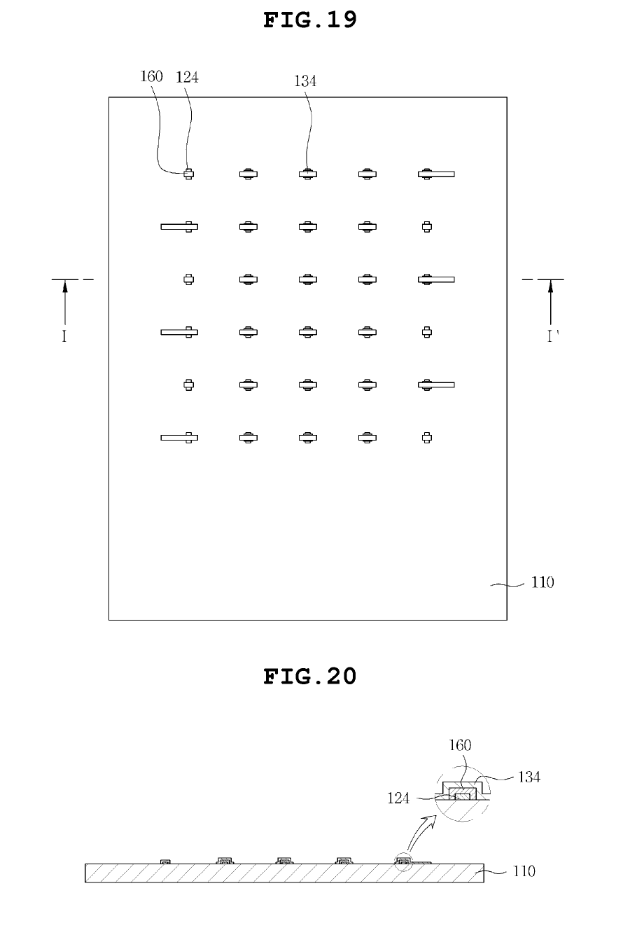

Thereafter, the second connection unit 134 is formed on the insulating pattern 160 as shown in FIGS. 19 and 20. The second connection unit 134 is formed in the X direction like the insulating pattern 160 and both distal ends thereof are formed on the base substrate 110. It is sufficient to form the second connection unit 134 only on the insulating pattern 160 which will form the bridge structure.

As shown in FIGS. 15 to 20, the method of manufacturing a touch screen according to the embodiment first forms the bridge structure that is configured of the first connection unit 124, the insulating pattern 160, and the second connection unit 134 and then, forms other configurations. After it confirms whether a short occurs between the first connection unit 124 and the second connection unit 134 by first forming the bridge structure having a complicated structure, the following process may be performed, thereby making it possible to reduce a defect rate.

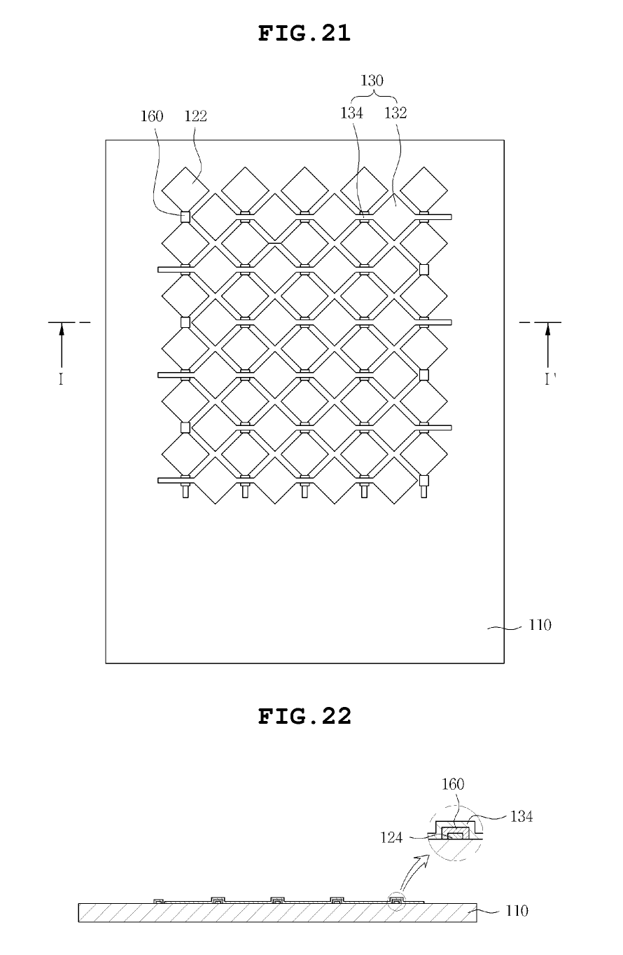

Next, as shown in FIGS. 21 to 24, the first electrode pattern 120 is formed by forming the first sensing unit 122 connected to the first connection unit 124 on the upper surface of the base substrate and the second electrode pattern 130 is formed by forming the second sensing unit 132 connected to the second connection unit 134, thereby removing the insulating pattern 160.

At this time, the shape of the first sensing unit 122 and the second sensing unit 132 and the removal of the insulating pattern 160 may be continuously conducted regardless of a sequence. However, unlike the manufacturing method according to the first embodiment, the first sensing unit 122 and the second sensing unit 132 are simultaneously formed.

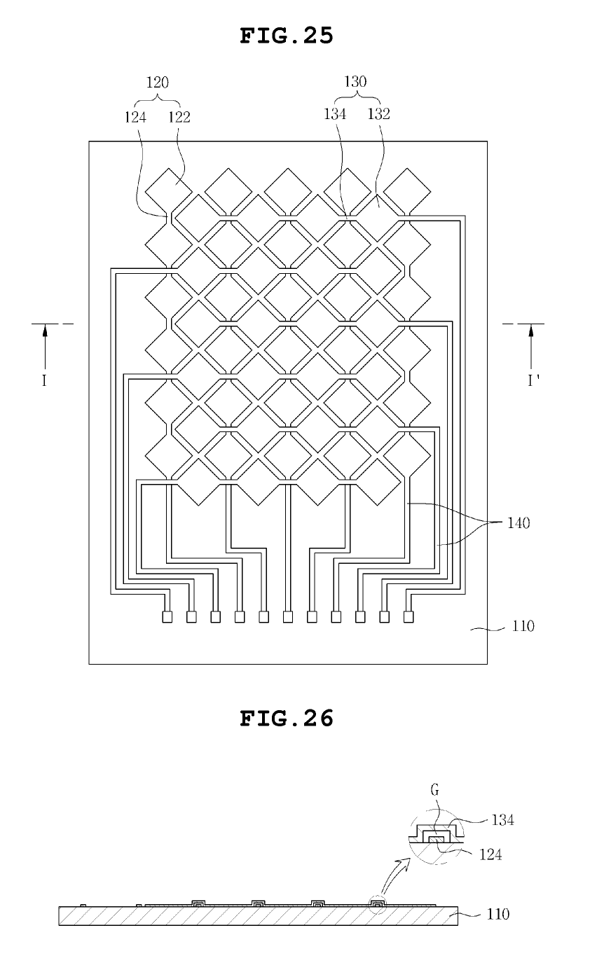

As shown in FIGS. 25 and 26, the method of manufacturing a touch screen according to the present invention further includes forming the electrode wiring 140 connected to the first electrode pattern 120 and the second electrode pattern 130. The forming the electrode wiring 140 may be performed regardless of the process sequence as described with reference to FIGS. 11 and 12. For example, the electrode wiring 140 may be previously formed in the inactive region prior to forming the bridge structure and may be formed to connect to the first electrode pattern 120 and the second electrode pattern 10 after forming the first electrode pattern 120 and the second electrode pattern 130 as shown in FIGS. 25 and 26.

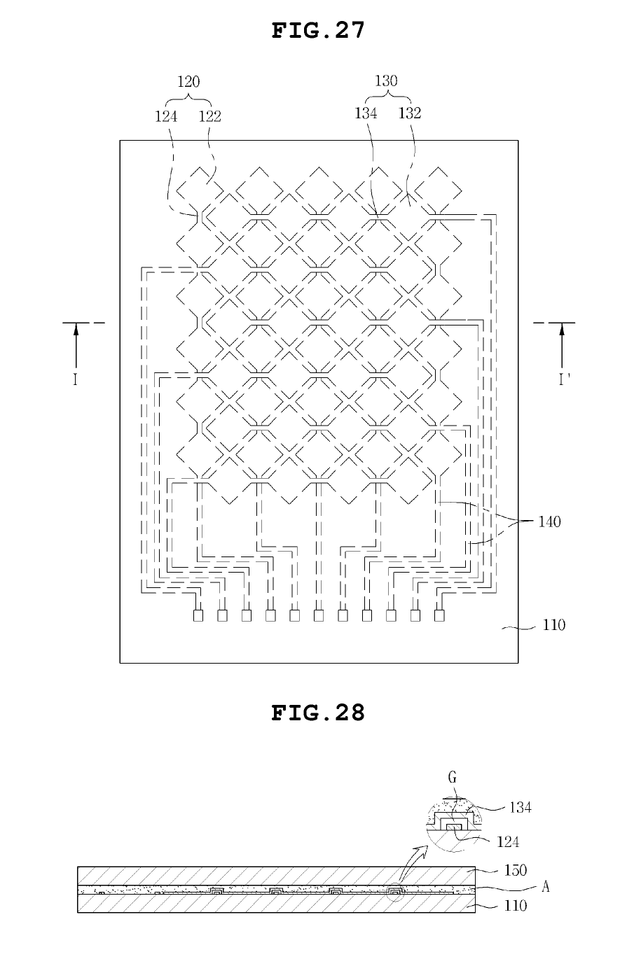

Further, as shown in FIGS. 27 and 28, the method of manufacturing a touch screen according to the present invention further includes forming the protective layer 150 on the base substrate 110 to cover the first electrode pattern 120, the second electrode pattern 130, and the electrode wiring.

The touch screen according to the present invention can be formed in a slim structure by being formed with a one-layer structure.

Further, the present invention can reduce the parasitic capacitance by forming bridge structures having an air gap there between at the intersecting point at the time of forming two types of electrode patterns on the same plane.

The method of manufacturing a touch screen according to the present invention is performed by a method of forming the insulating pattern that forms a bridge structure and then removing the insulating pattern, thereby making it possible to prevent a short from occurring in the bridge structures because the bridge structures are firmly formed even with the air gap there between.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A one-layer capacitive touch screen, comprising:
a base substrate:
a first electrode pattern that is formed on an upper surface of the base substrate and includes a plurality of first sensing units and first connection units connecting the adjacent first sensing units;
a second electrode pattern that is formed on the upper surface of the base substrate and includes a plurality of second sensing units and second connection units connecting the adjacent second sensing units, the second connection units being formed to intersect with each other on the upper side of the first connection unit, having an air gap therebetween; and
an electrode wiring that is connected to the first electrode pattern and the second electrode pattern.

2. The one-layer capacitive touch screen as set forth in claim 1, further comprising a protective layer that is formed on the base substrate and covers the first electrode pattern, the second electrode pattern, and the electrode wiring.

3. The one-layer capacitive touch screen as set forth in claim 1, wherein the first electrode pattern and the second electrode pattern are made of conductive polymer.

4. The one-layer capacitive touch screen as set forth in claim 1, wherein the first sensing unit and the second sensing unit are formed in a polygonal shape.

5. A method of manufacturing a one-layer capacitive touch screen, comprising:
forming a first electrode pattern, which includes a plurality of first sensing units and first connection units connecting the adjacent first sensing units, on the upper surface of a base substrate;
forming an insulating pattern on the first connection unit;
forming a second electrode pattern, which includes a plurality of second sensing units and second connection units connecting the adjacent second sensing units and disposed on the insulating pattern, on the upper surface of the base substrate; and
removing the insulating pattern.

6. The method of manufacturing a one-layer capacitive touch screen as set forth in claim 5, further comprising forming an electrode wiring that is connected to the first electrode pattern and the second electrode pattern.

7. The method of manufacturing a one-layer capacitive touch screen as set forth in claim 6, further comprising after removing the insulating pattern, forming a protective layer to cover the first electrode pattern, the second electrode pattern, and the electrode wiring.

8. The method of manufacturing a one-layer capacitive touch screen as set forth in claim 5, wherein the forming the insulating pattern is performed by bonding an insulating film having an adhesive layer formed on one surface thereof on the first connection unit.

9. The method of manufacturing a one-layer capacitive touch screen as set forth in claim 5, wherein the forming the insulating pattern is performed by spotting a semisolid insulating material on the first connection unit.

10. The method of manufacturing a one-layer capacitive touch screen as set forth in claim 5, wherein the forming the insulating pattern forms the insulating pattern to cover the side surface and upper surface of the first connection unit.

11. The method of manufacturing a one-layer capacitive touch screen as set forth in claim 5, wherein at the forming the first electrode pattern and the forming the second electrode pattern, the first electrode pattern and the second electrode pattern are formed by an inkjet printing scheme.

12. A method of manufacturing a one-layer capacitive touch screen, comprising:
forming a plurality of first connection units having an array form on an upper surface of a base substrate;
forming an insulating pattern on the first connection unit;
forming a second connection unit that is formed on the insulating pattern and has both distal ends to be formed on the base substrate;
forming a first electrode pattern on the upper surface of the base substrate by forming a first sensing unit connecting to the first connection unit and forming a second electrode pattern by forming a second sensing unit connecting to the second connection unit; and
removing the insulating pattern.

13. The method of manufacturing a one-layer capacitive touch screen as set forth in claim 12, further comprising forming an electrode wiring connected to the first electrode pattern and the second electrode pattern.

14. The method of manufacturing a one-layer capacitive touch screen as set forth in claim 12, further comprising forming a protective layer to cover the first electrode pattern, the second electrode pattern, and the electrode wiring.

15. The method of manufacturing a one-layer capacitive touch screen as set forth in claim 12, wherein the forming the insulating pattern is performed by bonding an insulating film having an adhesive layer formed on one surface thereof on the first connection unit.

16. The method of manufacturing a one-layer capacitive touch screen as set forth in claim 12, wherein the forming the insulation pattern is performed by spotting a semisolid insulating material on the first connection unit.

17. The method of manufacturing a one-layer capacitive touch screen as set forth in claim 12, wherein at the forming the first electrode pattern and the forming the second electrode pattern, the first electrode pattern and the second electrode pattern are formed by an inkjet printing scheme.
